(19) United States
(12) Patent Application Publication
(10) Pub. No.: US 2009/0045406 A1
(43) Pub. Date: Feb. 19, 2009

(54) SEMICONDUCTOR DEVICE AND DISPLAY DEVICE

(75) Inventors: Katsumi Matsumoto, Mobara (JP); Kozo Yasuda, Mobara (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(73) Assignee: Hitachi Displays, Ltd.

(21) Appl. No.: 12/189,918

(22) Filed: Aug. 12, 2008

(30) Foreign Application Priority Data
Aug. 13, 2007 (JP) 2007-210716

(51) Int. Cl. H01L 29/786; H01L 33/00

(52) U.S. Cl. 257/66; 257/72; 257/E29.292; 257/E33.003

(57) ABSTRACT

A semiconductor device which can realize a diode function is provided with a manufacturing process of a polysilicon thin film transistor and without adding a dedicated process. A semiconductor device is provided having a semiconductor layer comprising a low-concentration p-type polysilicon region formed over a substrate, the semiconductor device comprising a high-concentration p-type polysilicon region and a high-concentration n-type polysilicon region which are formed over the substrate on both sides of the low-concentration p-type polysilicon region, an insulating film which is formed over the high-concentration p-type polysilicon region, the low-concentration p-type polysilicon region, and the high-concentration n-type polysilicon region, and a control electrode which is formed over the insulating film and over the low-concentration p-type polysilicon region, wherein the control electrode is electrically connected to one of the high-concentration p-type polysilicon region and the high-concentration n-type polysilicon region.

### CROSS-REFERENCE TO RELATED APPLICATIONS

The present application claims priority from Japanese application JP 2007-210716 filed on Aug. 13, 2007, the content of which is hereby incorporated by reference into this application.

### BACKGROUND OF THE INVENTION

1. Field of the Invention

The present invention relates to a semiconductor device and a display device, and, in particular, to a diode comprising polysilicon (polycrystalline silicon).

2. Description of Related Art

A TFT-type liquid crystal display device which has a thin film transistor (TFT) as an active element is employed in many applications such as, for example, a high-resolution color monitor for a computer or for other information devices and a display device of a television receiver.

Conventionally, in a TFT-type liquid crystal display device, a thin film transistor having a semiconductor layer formed with amorphous silicon (hereinafter referred to as “amorphous silicon thin film transistor”) has been used as the active element.

However, in recent years, TFT-type liquid crystal display devices which use a thin film transistor having the semiconductor layer formed with polysilicon (hereinafter referred to as “polysilicon thin film transistor”) as an active element (the display device will hereinafter be referred to as “Poly-SiTr liquid crystal display device”) are also in use.

In a polysilicon thin film transistor, a circuit can be formed on a glass substrate which is cheaper than the crystalline silicon through a low-temperature polysilicon technology or the like. Because of this, the Poly-SiTr liquid crystal display devices are particularly in use as the display for a portable phone or the like.

In addition, the polysilicon thin film transistor has an operation speed which is faster than amorphous silicon thin film transistors (approximately two digits higher mobility). Because of this, in the Poly-SiTr liquid crystal display devices, the peripheral circuits can also be formed on the substrate of the liquid crystal display panel.

In recent years, a system-integrated panel is researched in which all of the functions of semiconductor chips added on the liquid crystal display panel are integrated into a circuit formed with the polysilicon thin film transistor formed on the glass substrate, and the necessary driving circuit or the like can be simultaneously formed with the thin film transistor (active element) in a display region.

As a related art document related to the present invention, there is known a reference, “Nikkei Electronics”, Nikkei McGraw-Hill Inc., Feb. 28, 1994, pp. 103-109.

### SUMMARY OF THE INVENTION

However, currently, there are many problems in realizing the system-integrated panel using the polysilicon thin film transistor. Although the polysilicon thin film transistor has a higher mobility than the amorphous silicon thin film transistor, the performance of the transistor (such as speed and characteristic variation) is far inferior than the transistor having the semiconductor layer formed with crystalline silicon (hereinafter referred to as “silicon transistor”). Because of this, a problem arises in that a circuit performance equivalent to that of a liquid crystal display panel with an external semiconductor chip cannot be obtained with equivalent power consumption. Therefore, currently, the circuit is integrated in consideration of the total advantage of the final product. In this case, a passive device such as a diode is required in addition to the thin film transistor as the switching function.

In order to realize a diode function with a polysilicon thin film transistor, normally, a diode-connected polysilicon thin film transistor is used in which a gate (G) and a source (S) of a polysilicon thin film transistor are connected or the gate (G) and a drain (D) of the polysilicon thin film transistor are connected.

However, the characteristic variation in the polysilicon thin film transistor is larger compared to the characteristic variation in the silicon transistor. Thus, a diode formed with a diode-connected polysilicon thin film transistor also has the variation in the characteristic.

In particular, the variation in the threshold voltage (Vth) of the polysilicon thin film transistor is large. Because the threshold voltage of the polysilicon thin film transistor is set to be higher (on the enhance-side) compared to the silicon transistor in consideration of the variation, the variation in the threshold voltage leads to variation in the diode characteristic and, consequently, performance degradation.

A concrete example will now be described with reference to FIGS. 9 and 10.

FIG. 9 shows an example configuration of a charge-pump-type voltage boosting power supply circuit using a diode (D) and a capacitor (C). In the voltage boosting power supply circuit of FIG. 9, when the amplitude of the input voltage is Vin, the output voltage (Vout) is Vout≈3×Vin−6×VD. Here, VD represents a voltage drop in the forward direction of the diode.

FIG. 10 shows an example circuit in which the voltage boosting power supply circuit of FIG. 9 is constructed using a diode-connected polysilicon thin film transistor (TFT). In the voltage boosting power supply circuit of FIG. 10, when the amplitude of the input voltage is Vin, the output voltage (Vout) is Vout≈3×Vin−(Vth1+Vth2+Vth3+Vth4+Vth5+Vth6). Here, Vth represents a threshold voltage of the diode-connected polysilicon thin film transistor (TFT).

In the voltage boosting power supply circuit of FIG. 10, the threshold voltage (Vth) of the diode-connected polysilicon thin film transistor (TFT) is large. This large threshold voltage leads to a boosted voltage loss for each stage and variation in the final boosted voltage.

As a method of avoiding the variation in the threshold voltage (Vth) of the diode-connected polysilicon thin film transistor (TFT) as described above, a method is known which uses a pn junction diode. However, the junction of a p-type semiconductor layer of a high concentration and an n-type semiconductor layer of a high concentration does not have a reverse direction tolerance. Therefore, in general, a pin structure is used in which a low concentration layer (an I layer or an n-layer or a p-layer) is sandwiched between the p-type semiconductor layer and the n-type semiconductor layer.

However, in many cases, the pin structure cannot be realized with a manufacturing process of the polysilicon semiconductor device. Because of this, in many cases, a dedicated manufacturing process for the pin structure must be added to the manufacturing process of the polysilicon semiconductor device. In other words, a process load is applied to the manufacturing process of the polysilicon semiconductor device.

The present invention has been conceived in view of the above-described circumstances, and an advantage of the present invention is that a semiconductor device is provided in which a diode function can be realized with a manufacturing process of the polysilicon thin film transistor without adding a dedicated process.

Another advantage of the present invention is that a display device which uses the above-described semiconductor device is provided.

Above-described and other advantages and characteristics of the present invention will become apparent with the description of the present specification and the attached drawings.

According to various aspect of the present invention, the following devices are provided:

(1) a semiconductor device having a semiconductor layer comprising a low-concentration p-type polysilicon region formed over a substrate, the semiconductor device comprising a high-concentration p-type polysilicon region and a high-concentration n-type polysilicon region which are formed over the substrate on both sides of the low-concentration p-type polysilicon region, an insulating film which is formed over the high-concentration p-type polysilicon region, the low-concentration p-type polysilicon region, and the high-concentration n-type polysilicon region, and a control electrode which is formed over the insulating film and over the low-concentration p-type polysilicon region, wherein the control electrode is electrically connected to one of the high-concentration p-type polysilicon region and the high-concentration n-type polysilicon region;

(2) a semiconductor device having a semiconductor layer comprising a low-concentration n-type polysilicon region formed over a substrate, the semiconductor device comprising a high-concentration p-type polysilicon region and a high-concentration n-type polysilicon region which are formed over the substrate on both sides of the low-concentration n-type polysilicon region, an insulating film which is formed over the high-concentration p-type polysilicon region, the low-concentration n-type polysilicon region, and the high-concentration n-type polysilicon region, and a control electrode which is formed over the insulating film and over the low-concentration n-type polysilicon region, wherein the control electrode is electrically connected to one of the high-concentration p-type polysilicon region and the high-concentration n-type polysilicon region;

(3) a semiconductor device according to (1), wherein the substrate is a glass substrate;

(4) a display device comprising a display panel having a plurality of sub-pixels and a driving circuit which drives the plurality of sub-pixels, wherein the driving circuit comprises a diode, the diode comprises a semiconductor layer comprising a low-concentration p-type polysilicon region formed over a substrate, a high-concentration p-type polysilicon region and a high-concentration n-type polysilicon region which are formed over the substrate on both sides of the low-concentration p-type polysilicon region, an insulating film which is formed over the high-concentration p-type polysilicon region, the low-concentration p-type polysilicon region, and the high-concentration n-type polysilicon region, and a control electrode which is formed over the insulating film and over the low-concentration p-type polysilicon region, wherein the control electrode is electrically connected to one of the high-concentration p-type polysilicon region and the high-concentration n-type polysilicon region;

(5) a display device according to (4), wherein the driving circuit comprises a voltage boosting circuit having the diode and a capacitor; and

(6) a display device according to (4), wherein the driving circuit comprises a voltage generating circuit in which a plurality of the diodes are connected in series.

According to various aspects of the present invention, the following advantage can be obtained.

According to the present invention, a diode function can be realized with a manufacturing process of a polysilicon thin film transistor without adding a dedicated process.

### BRIEF DESCRIPTION OF THE DRAWINGS

FIG. 1 is a diagram schematically showing an example structure of a semiconductor device of a preferred embodiment according to the present invention.

FIG. 2 is a cross-sectional diagram showing an example cross-sectional structure of a semiconductor device of FIG. 1.

FIG. 3 is a diagram schematically showing an example structure of an alternative example of a semiconductor device of a preferred embodiment according to the present invention.

FIG. 4 is a diagram schematically showing an example structure of an alternative example of a semiconductor device of a preferred embodiment according to the present invention.

FIG. 5 is a diagram schematically showing an example structure of an alternative example of a semiconductor device of a preferred embodiment according to the present invention.

FIG. 6 is a graph showing relationship of voltage (V)-current (A) in an example of a semiconductor device of a preferred embodiment according to the present invention.

FIG. 7 is a diagram showing an example of a peripheral circuit to which a semiconductor device of a preferred embodiment according to the present invention is applied.

FIG. 8 is a diagram showing an example of a peripheral circuit to which a semiconductor device of a preferred embodiment according to the present invention is applied.

FIG. 9 is a circuit diagram showing an example of a charge-pump-type voltage boosting power supply circuit using a diode (D) and a capacitor (C).

FIG. 10 is a circuit diagram showing an example of a voltage boosting power supply circuit in which the voltage boosting power supply circuit of FIG. 9 is constructed with a diode-connected polysilicon thin film transistor.

### DETAILED DESCRIPTION OF THE INVENTION

A preferred embodiment of the present invention will now be described in detail with reference to the drawings.

In the description of the preferred embodiment, elements in the drawings having the same function are assigned the same reference numerals and will not be repeatedly described.

FIG. 1 is a diagram schematically showing an example structure of a semiconductor device of the present embodiment.

A semiconductor device of FIG. 1 realizes, with a manufacturing process of a polysilicon thin film transistor, a diode which is not affected by a characteristic variation in the thin film transistor without applying a process load.

As shown in FIG. 1, the semiconductor device of the present embodiment comprises a control electrode 1, a semiconductor layer 20 comprising a low-concentration p-type polysilicon region, a high-concentration p-type polysilicon region 22, and a high-concentration n-type polysilicon region 23. In FIG. 1, the high-concentration p-type polysilicon region 22 and the control electrode 1 are electrically connected.

The structure of FIG. 1 differs from a typical polysilicon thin film transistor (TFT) in that the high-concentration p-type polysilicon region 22 and the high-concentration n-type polysilicon region 23 are formed sandwiching the semiconductor layer 20, and the structure of FIG. 1 shows a diode characteristic.

The high-concentration p-type polysilicon region 22 corresponds to an anode region and the high-concentration n-type polysilicon region 23 corresponds to a cathode region.

The formation of the high-concentration p-type polysilicon region 22 and the high-concentration n-type polysilicon region 23 having different conductive types sandwiching the semiconductor layer 20 can be realized by setting the mask during an impurity implantation in the manufacturing process of the polysilicon thin film transistor as a photoresist and already-formed gate. A low-concentration impurity layer in a channel below the gate can be substituted with the normal Vth controlling implantation of nMOS and pMOS.

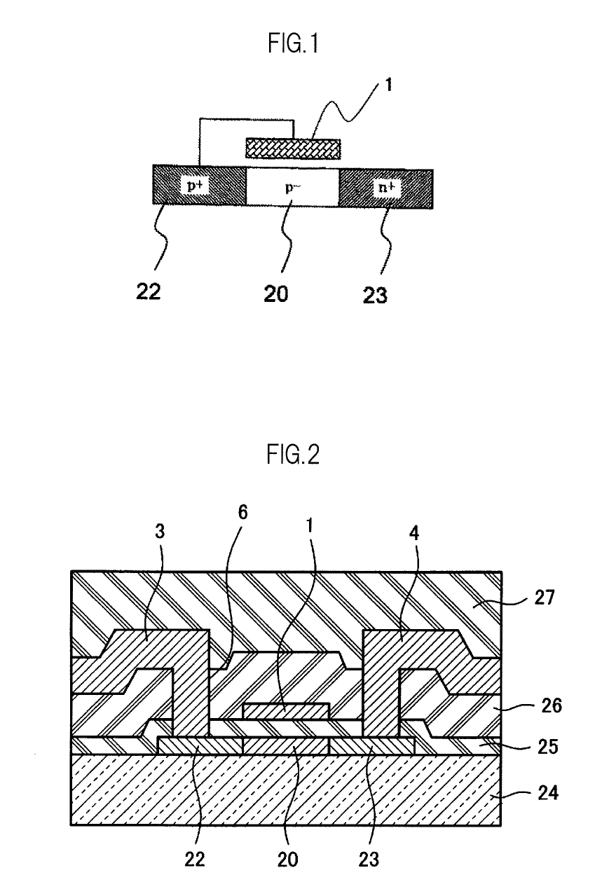

FIG. 2 is a cross-sectional view showing an example cross sectional structure of the semiconductor device of FIG. 1.

As shown in FIG. 2, in the semiconductor device of the present embodiment, the high-concentration p-type polysilicon region 22, the semiconductor layer 20, and the high-concentration n-type polysilicon region 23 are formed over a substrate 24 (for example, glass substrate). In addition, a first interlayer insulating film 25 is formed over the high-concentration p-type polysilicon region 22, the semiconductor layer 20, and the high-concentration n-type polysilicon region. The control electrode 1 is formed above the semiconductor layer 20 and over the first interlayer insulating film 25. A second interlayer insulating film 26 is formed over the control electrode 1. Moreover, a first wiring layer 3 and a second wiring layer 4 are formed over the second interlayer insulating film 26. Furthermore, a protection film 27 covers the first wiring layer 3 and the second wiring layer 4.

The first wiring layer 3 is connected to the high-concentration p-type polysilicon region 22 and to the control electrode 1 through a through hole 6 formed through the interlayer insulating films 25 and 26.

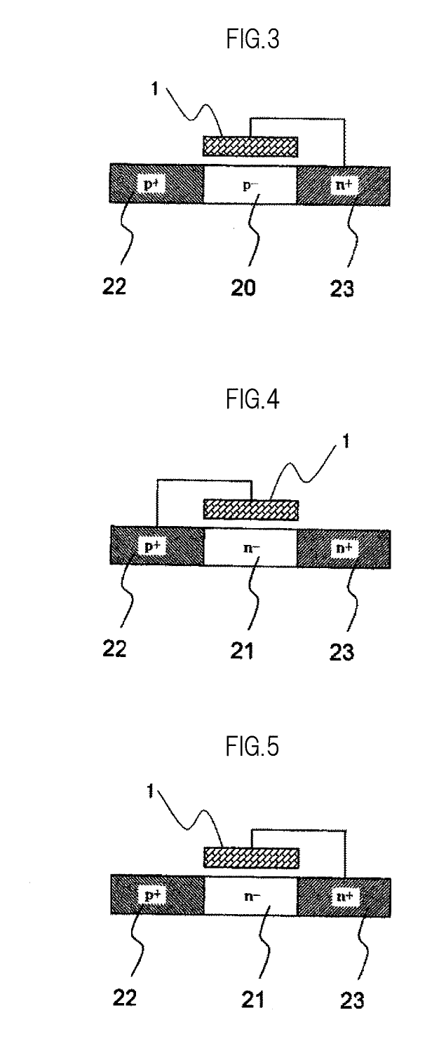

FIGS. 3-5 are diagrams schematically showing alternative example structures of the semiconductor device of the present embodiment.

The semiconductor device shown in FIG. 3 is similar to the semiconductor device of FIG. 1 except that the control electrode 1 and the high-concentration n-type polysilicon region 23 are electrically connected in place of the electrical connection of the control electrode 1 and the high-concentration p-type polysilicon region 22.

The semiconductor device of FIG. 4 is similar to the semiconductor device of FIG. 1 except that a semiconductor layer 21 comprising a low-concentration n-type polysilicon region is used in place of the semiconductor layer 20 comprising the low-concentration p-type polysilicon region.

The semiconductor device of FIG. 5 is similar to the semiconductor device of FIG. 3 except that the semiconductor layer 21 comprising a low-concentration n-type polysilicon region is used in place of the semiconductor layer 20 comprising the low-concentration p-type polysilicon region. Each of the structures of FIGS. 3-5 also shows a diode characteristic.

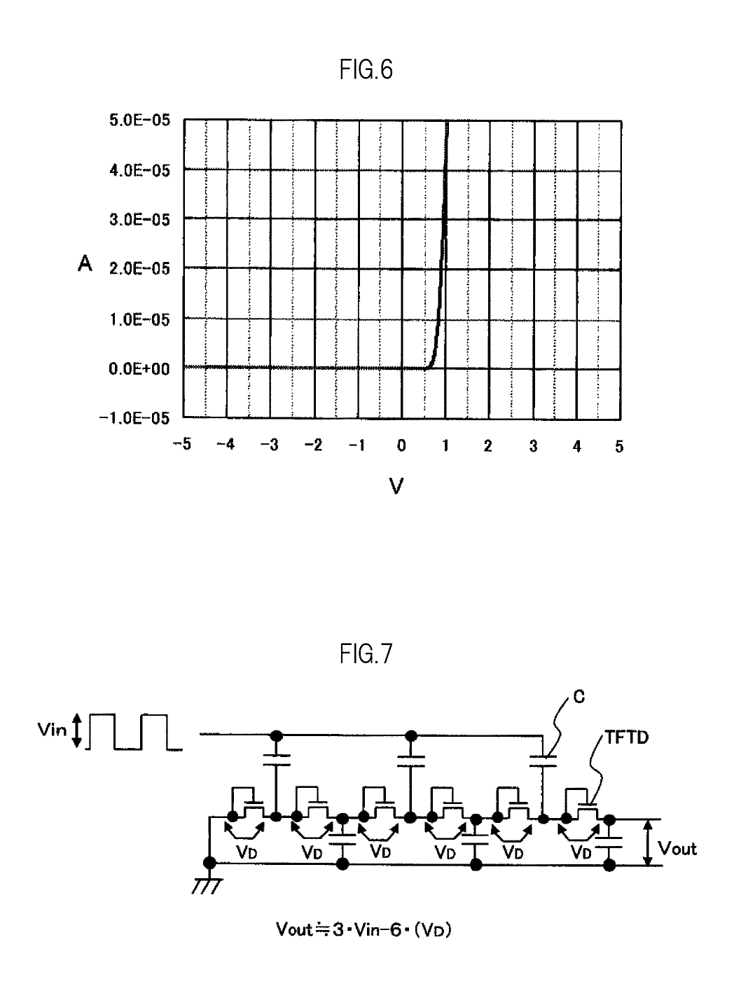

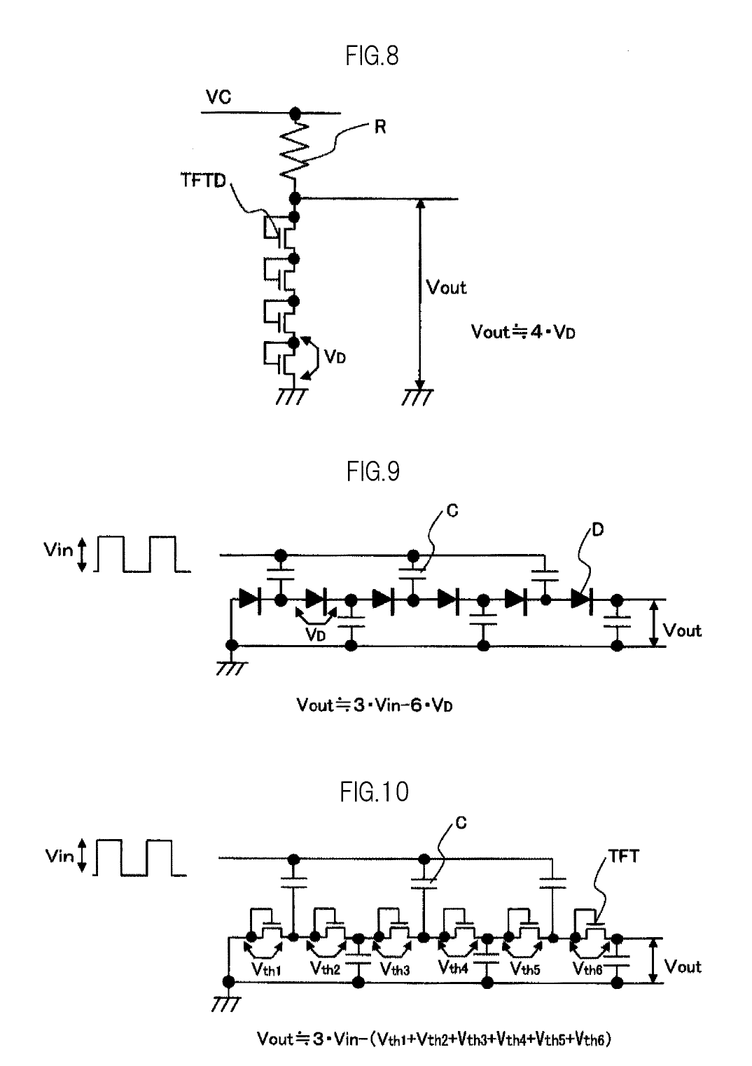

FIG. 6 is a graph showing a relationship of voltage (V)-current (A) in an example structure of a semiconductor device of the present embodiment. Based on FIG. 6, it can be seen that the semiconductor device of the present embodiment shows a diode characteristic. In the diode characteristic shown in FIG. 6, the voltage drop in the forward direction (VD) is approximately 0.7 V similar to the diode formed with crystalline silicon.

As described, according to the present embodiment, a diode having a small characteristic variation can be realized without increasing the manufacturing cost. In other words, according to the present embodiment, although the structure is a pin-structured diode, because the low-concentration region forming a part of the semiconductor layer can be formed simultaneously with the channel layer below the gate electrode, a diode having a low characteristic variation can be realized without a processing load and without an increase in the manufacturing cost.

As described, in the Poly-SiTr liquid crystal display device (for example, a liquid crystal display device for a portable phone), the peripheral circuit can also be formed on the substrate forming a part of the liquid crystal display panel.

The semiconductor device of the present embodiment can be applied to a peripheral circuit, among the peripheral circuits of the Poly-SiTr liquid crystal display device, which requires a diode characteristic. Of course, the peripheral circuit to which the semiconductor device of the present embodiment is applied is formed on one of a pair of substrates (for example, glass substrates) forming a part of the liquid crystal display panel, simultaneously with a pixel transistor forming a part of the active element of each sub-pixel of the liquid crystal display panel.

FIGS. 7 and 8 are diagrams showing examples of peripheral circuits to which the semiconductor device of the present invention is applied.

FIG. 7 is a diagram showing a voltage boosting power supply circuit similar to the voltage boosting power supply circuit of FIG. 10 except that the semiconductor device (TFTD) of the present invention having a pin diode function is used in place of the diode-connected polysilicon thin film transistor. In the voltage boosting power supply circuit of FIG. 7, when the amplitude of the input voltage is Vin, the output voltage (Vout) is Vout≈3×Vin−6×VD. Here, VD represents a voltage drop in the forward direction of the semiconductor device (TFTD) of the present invention. With the use of the semiconductor device of the present invention, a stable power supply voltage can be obtained.

FIG. 8 is a circuit diagram showing an example structure of a voltage generating circuit. The circuit of FIG. 8 is constructed by connecting four semiconductor devices (TFTD) of the present invention having the pin diode function are connected in series between a voltage of VC and a reference voltage (GND) with a current controlling resistor (R) between the voltage of VC and the semiconductor device.

In the voltage generating circuit of FIG. 8, the output voltage (Vout) is approximately four times VD, that is, Vout≈4×VD. Here, VD represents the voltage drop in the forward direction of the semiconductor device (TFTD) of the present invention. With the use of the semiconductor device (TFTD) of the present invention, a voltage with a low variation can be obtained.

The semiconductor device of the present invention is not limited to the liquid crystal display device, and may be applied to, for example, a peripheral circuit, among peripheral circuits formed over a substrate of a display panel in general display devices having pixels such as an organic electroluminescence display device, which requires a diode characteristic.

While there have been described what are at present considered to be certain embodiments of the invention, it will be understood that various modifications may be made thereto, and it is intended that the appended claims cover all such modifications as fall within the true spirit and scope of the invention.

What is claimed is:

1. A semiconductor device having a semiconductor layer comprising a low-concentration p-type polysilicon region formed over a substrate, the semiconductor device comprising:
a high-concentration p-type polysilicon region and a high-concentration n-type polysilicon region which are formed over the substrate on both sides of the low-concentration p-type polysilicon region;
an insulating film which is formed over the high-concentration p-type polysilicon region, the low-concentration p-type polysilicon region, and the high-concentration n-type polysilicon region; and
a control electrode which is formed over the insulating film and over the low-concentration p-type polysilicon region, wherein the control electrode is electrically connected to one of the high-concentration p-type polysilicon region and the high-concentration n-type polysilicon region.

2. A semiconductor device having a semiconductor layer comprising a low-concentration n-type polysilicon region formed over a substrate, the semiconductor device comprising:
a high-concentration p-type polysilicon region and a high-concentration n-type polysilicon region which are formed over the substrate on both sides of the low-concentration n-type polysilicon region;
an insulating film which is formed over the high-concentration p-type polysilicon region, the low-concentration n-type polysilicon region, and the high-concentration n-type polysilicon region; and
a control electrode which is formed over the insulating film and over the low-concentration n-type polysilicon region, wherein
the control electrode is electrically connected to one of the high-concentration p-type polysilicon region and the high-concentration n-type polysilicon region.

3. The semiconductor device according to claim 1, wherein
the substrate is a glass substrate.

4. A display device comprising a display panel having a plurality of sub-pixels and a driving circuit which drives the plurality of sub-pixels, wherein
the driving circuit comprises a diode,
the diode comprises:
a semiconductor layer comprising a low-concentration p-type polysilicon region formed over a substrate;
a high-concentration p-type polysilicon region and a high-concentration n-type polysilicon region which are formed over the substrate on both sides of the low-concentration p-type polysilicon region;
an insulating film which is formed over the high-concentration p-type polysilicon region, the low-concentration p-type polysilicon region, and the high-concentration n-type polysilicon region; and
a control electrode which is formed over the insulating film and over the low-concentration p-type polysilicon region, wherein the control electrode is electrically connected to one of the high-concentration p-type polysilicon region and the high-concentration n-type polysilicon region.

5. The display device according to claim 4, wherein
the driving circuit comprises a voltage boosting circuit having the diode and a capacitor.

6. The display device according to claim 4, wherein
the driving circuit comprises a voltage generating circuit in which a plurality of the diodes are connected in series.
